(19) United States
(12) Patent Application Publication
(10) Pub. No.: US 2007/0047200 A1
(43) Pub. Date: Mar. 1, 2007

(54) Fan cartridge assembly

(76) Inventor: Tai-Chi Huang, Taipei (TW)

Correspondence Address: LIN & ASSOCIATES INTELLECTUAL PROPERTY, P.O. BOX 2339, SARATOGA, CA, 95070-0339, US

(21) Appl. No.: 11/209,510

(22) Filed: Aug. 23, 2005

(51) Int. Cl. H05K 7/20

(52) U.S. Cl. 361/695

(57) ABSTRACT

A fan cartridge assembly includes a cartridge, a first fan and a second fan. The cartridge has a first round hole and a second round hole for receiving the first fan and the second fan. The cartridge has an air duct, one end of which is connected to the first round hole. A back plate is mounted to one end of the cartridge and has air vents connected to the other end of the air duct for exhausting air. When assembled in a computer case, the second fan drafts air blowing to interface cards and power chips in the computer to cool them down and the first fan expels the heated air from the inside of the computer case to the outside. This allows the operation of the computer to keep in a normal working status.

### BACKGROUND OF THE INVENTION

1. Field of the Invention

The present invention relates to a fan cartridge assembly used for heat dissipation of electronic products, and in particular to a fan cartridge assembly that is to be assembled in a personal computer for heat dissipation.

2. The Related Art

With such high speed the latest computers run, the CPU, video cards, and TV tuner cards often generate tremendous amount of heat and cause thermal problems for the internal components, if the heat is not properly and effectively ventilated away from the computer case. The heat will also cause the processor, power chips and other controllers to decrease the performance or malfunction.

Although some of common power chips used on video cards, PCI interface cards, accelerated graphics port (AGP) cards, TV tuner cards are sensitive to temperature change for optimum performance, these power chips themselves also creates more heat in high speed operation. Therefore, these chips shall be operated with highly efficient ventilators to help cooling down the temperature and keep the controller functioning normally.

A heat sink is often used for heat dissipation and mounted on top of semiconductor or controller, and a fan adaptor is mounted directly over the heat sink to create air circulation for the semiconductor to cool down the operating temperature. But the problem is that these fan adaptors can only fit on one particular type of heat sink, as the shapes and dimensions of the heat sink are vastly different. Also, the fan adaptor has to be mounted over the heat sink or interface card using screws or mechanical clipping devices, and these modification procedures inside the computer case are not easy for general users. Another way of installation is to mount a case fan at the back of the computer case, but that can only cover the rear section of the computer case and often produces high pitch noise due to high speed operation.

In these aspects, a fan cartridge assembly in accordance with the present invention substantially reduces or obviates limitations and disadvantages of the prior art, and enhances the computer operation.

### SUMMARY OF THE INVENTION

The primary objective of the present invention is to provide a fan cartridge assembly that can be fitted into a slot of a personal computer and arranged in parallel to interface cards inside the computer case.

The secondary objective of the present invention is to provide a fan cartridge assembly that can be easily assembled on a personal computer by general users.

The tertiary objective of the present invention is to provide a fan cartridge assembly that can be manufactured with cost effective performance.

To achieve the above-mentioned objectives, the fan cartridge assembly in accordance with the present invention comprises a cartridge, a first fan and a second fan received in the cartridge. The cartridge has a first round hole and a second round hole each having an inward extension rim extending from the periphery of each round hole, the cartridge has an air duct, one end of which is connected to the extension rim of the first round hole, and the two round holes are not communicated with each other. The first fan and the second fan are installed in the first round hole and the second round hole of the cartridge, respectively. A back plate, one end of which is mounted to one end of the cartridge for mounting the fan cartridge assembly on a slot of the computer case, has air vents connected to the other end of the air duct for exhausting air. The second fan drafts air blowing to video cards, chipsets and other internal components in the computer to cool them down and the first fan expels the heated air from the inside of the computer case to the outside.

In assembling, the fan cartridge assembly in accordance with the present invention is mounted in a slot of a computer case in parallel to interface cards at the backside of the computer case. The assembling does not require special techniques or tools. Only one screwdriver is needed to secure the back plate of the fan cartridge assembly in the slot with one or two screws.

Since the fan cartridge assembly drafts air blowing to power chips and interface cards and effectively expel the heated air to the outside, the temperature of the internal components can be rapidly reduced. This allows the operation of the computer to keep in a normal working status.

The airflow direction can be easily adjusted by turning the second fan to desired angles around a pivot joint thereof. Thus, this can create a better air circulation and further attain a more effective heat dissipation.

These along with other features of novelty, which characterize the present invention, are pointed out with particularity in the claims annexed to and forming a part of this disclosure. For a better understanding of the present invention, the operating advantages and the specific objectives attained by its uses, references should be made to the accompanying drawings and descriptive matter illustrated in preferred embodiments of the present invention.

### BRIEF DESCRIPTION OF THE DRAWINGS

FIG. 1 is a perspective view of a fan cartridge assembly in accordance with the present invention;

FIG. 2 is an exploded perspective view of the fan cartridge assembly of the present invention;

FIG. 3 is an assembly diagram of the fan cartridge assembly in a case slot of a personal computer;

FIG. 4 is a top view of FIG. 3 showing the direction of air flow inside the computer case; and

FIG. 5 is a top view of FIG. 3 showing that a second fan of the present invention is pivoted an angle.

### DETAILED DESCRIPTION OF THE PREFERRED EMBODIMENT

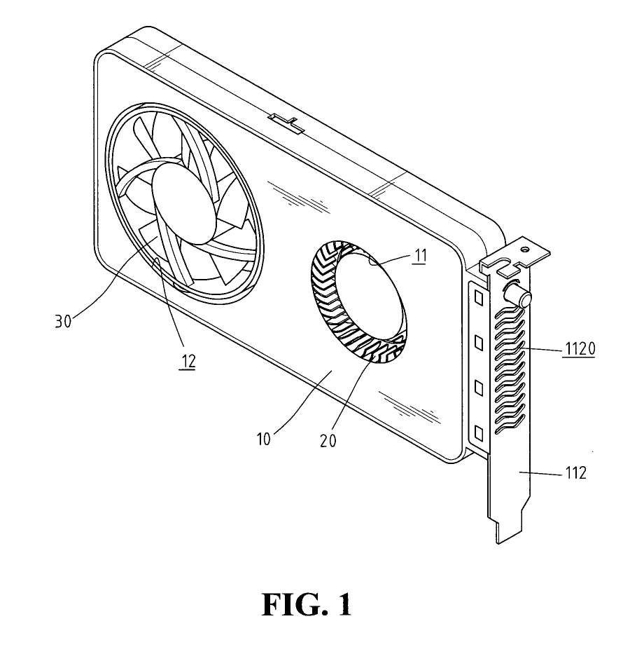

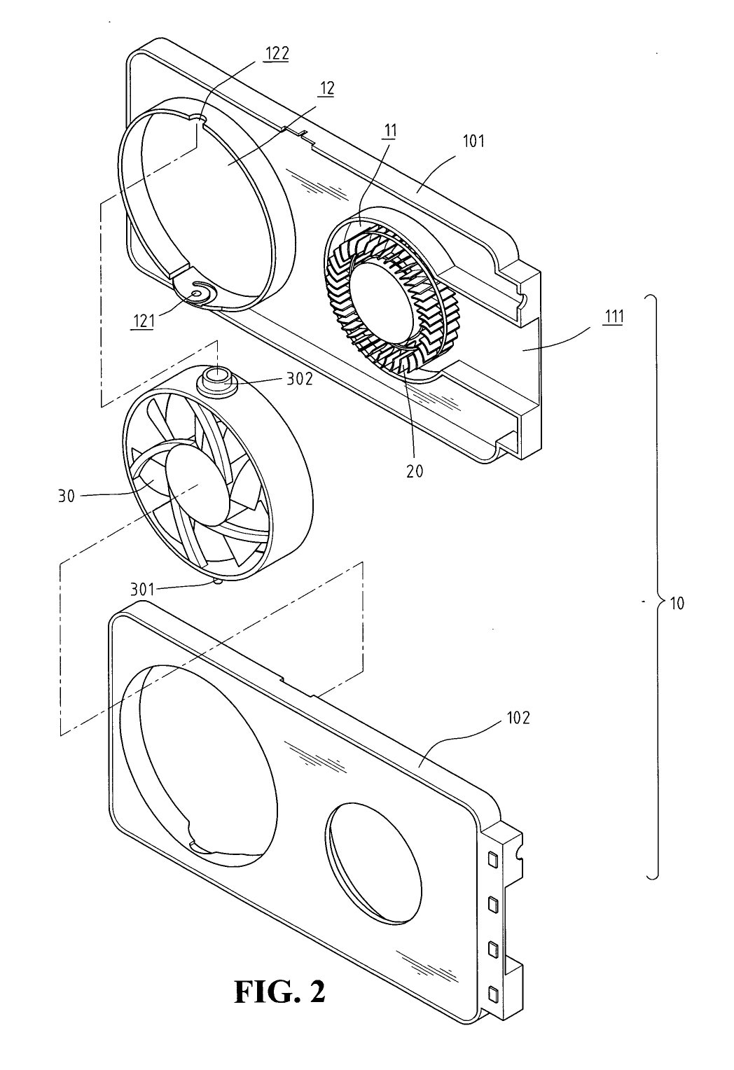

Referring to FIGS. 1 and 2, a fan cartridge assembly in accordance with the present invention comprises a cartridge 10, a first fan 20 and a second fan 30 received in the cartridge 10.

The cartridge 10 comprises a first half cartridge 101 and a second half cartridge 102 clipped and assembled together. A back plate 112 having a plurality of air vents 1120 is mounted on an end of the cartridge 10. The cartridge 10 forms a first round hole 11 and a second round hole 12 for housing the two fans 20, 30. The cartridge 10 has an air duct 111, one end of which is connected to the first round hole 11 and the other end is connected to the air vents 1120 on the back plate 112. The first round hole 11 and the second round hole 12 are formed in such a way that the two holes 11, 12 are hollowed out but not communicating with each other.

The first fan 20 is installed in the first round hole 11, which is a turbo centrifugal fan for drawing out the air from a computer case to which the fan cartridge assembly is mounted.

The second fan 30 is installed in the second round hole 12 and can be pivoted with respect to the cartridge 10, so that the airflow direction can be easily adjusted by turning the second fan 30 to face hot spots inside the computer case, thereby rapidly attaining the heat dissipation.

Each of the two round holes 11, 12 has an inward extension rim (not labeled) extending from the periphery of each hole. The second round hole 12 has a pivot hole 121 at a bottom of the rim and a notch 122 at a top of the rim for pivotably mounting with the second fan 30.

The outer edge of the second fan 30 has a pivot pin 301 at a bottom and a round stud 302 at a top thereof, which are, respectively, fitted into the pivot hole 121 and the notch 122 on the extension rim of the second round hole 12 for pivotably receiving and mounting the second fan 30 to the second round hole 12.

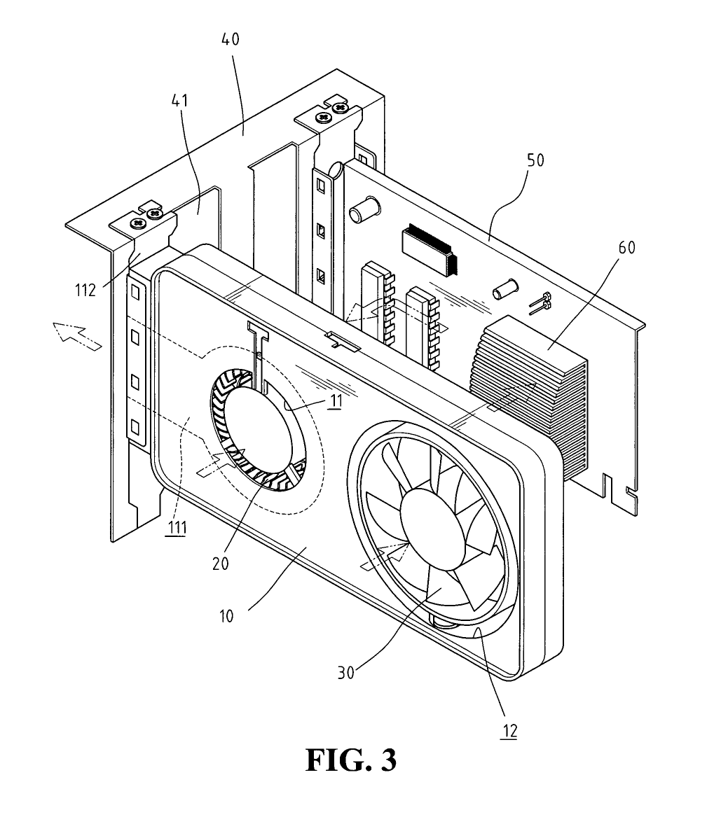

Referring to FIG. 3, when the fan cartridge assembly in accordance with the present invention is assembled to a computer case, the back plate 112 is mounted to a slot 41 of a slot plate 40 in the computer case. The air vents 1120 of the back plate 112 are faced to the outside through the slot 41 at a back of the computer case. The fan cartridge assembly shall be placed in parallel with interface cards 50 inside the computer case, such that it is directly positioned in front of hot spots on the interface card 50 or a power chip on a main board. Since the fan cartridge assembly is faced to the hot spots, for example a chip (not shown) or a heat sink 60 mounted over the chip, air is drafted by the second fan 30 and directly blown to the hot spots such that the heat can be rapidly dissipated from the surface of the hot spots and the heated air can be expelled by the first fan 20 to the outside through the air duct 111, the air vents 1120 and the slot 41.

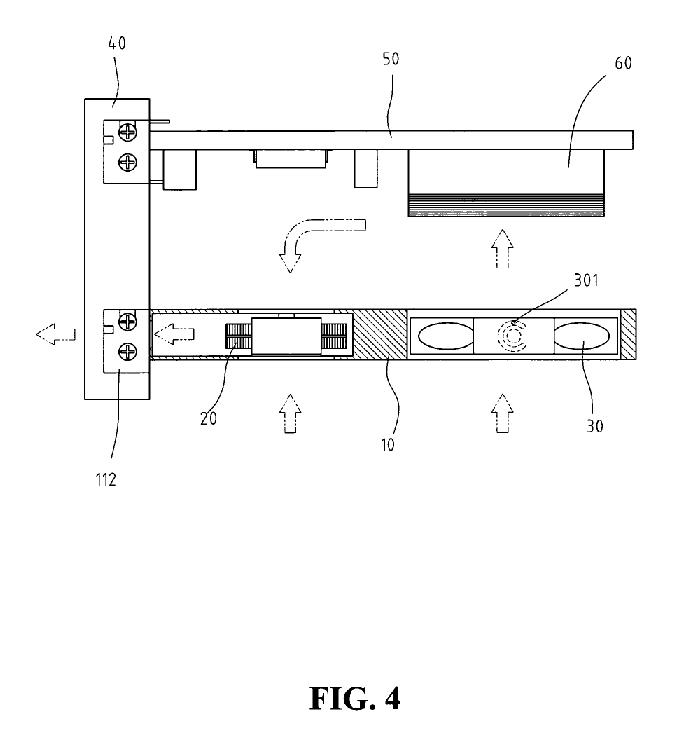

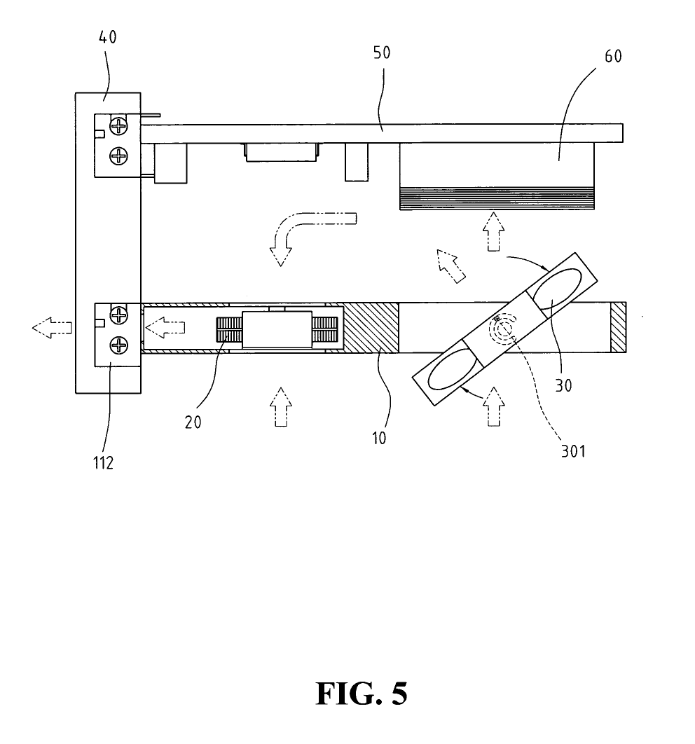

Referring to FIG. 4, in the usual case, since the fan cartridge assembly in accordance with the present invention is disposed in parallel with interface cards 50 and the first fan 20 and second fan 30 are placed at the back side of the cards, the two fans 20, 30 can only blow air to those components on the back side of the computer case. Also Referring to FIG. 5, the pivot joint on the second fan 30 allows the second fan 30 to be turned in different angles, so that the airflow can be directed to other desired areas. This works in conjunction with the first fan 20 to create an optimal airflow in the computer case.

Compared with the conventional fans and case fans, the fan cartridge assembly in accordance with the present invention can make a good air circulation over the CPU and video cards and effectively expel heat in the computer case to the outside. This allows the operation of the computer to keep in a normal working status.

Although the present invention has been described with reference to the preferred embodiments thereof, it is apparent to those skilled in the art that a variety of modifications and changes may be made with regard to different forms and shapes without departing from the spirit and scope of the present invention which is intended to be defined by the appended claims.

What is claimed is:

1. A fan cartridge assembly, comprising:
a cartridge having a first round hole and a second round hole each having an inward extension rim extending from the periphery of each round hole, the cartridge having an air duct, one end of which is connected to the extension rim of the first round hole, and the two round holes being not communicated with each other;
a first fan installed in the first round hole of the cartridge;
a second fan installed in the second round hole of the cartridge; and
a back plate, one end of which is mounted to one end of the cartridge, having air vents connected to the other end of the air duct for exhausting air;
wherein when the fan cartridge assembly is assembled to a computer case, the other end of the back plate is mounted to a slot of a slot plate of the computer case, the air vents of the back plate is aligned with the slot of the slot plate, and the cartridge is arranged in parallel with interface cards mounted in slots of the slot plate.

2. The fan cartridge assembly as claimed in claim 1, wherein the cartridge comprises a first half cartridge and a second half cartridge clipped and assembled together for holding the first fan and the second fan in place.

3. The fan cartridge assembly as claimed in claim 1, wherein the first round hole and the second round holes each is hollowed out.

4. The fan cartridge assembly as claimed in claim 1, wherein the second round hole has a pivot hole at a bottom of the extension rim and a notch at a top of the extension rim; and the second fan has a pivot pin at a bottom of the outer edge and a round stud at a top of the outer edge, which are, respectively, fitted into the pivot hole and the notch on the extension rim of the second round hole for pivotably mounting the second fan to the second round hole of the cartridge.

5. The fan cartridge assembly as claimed in claim 1, wherein the first fan is a turbo centrifugal fan.
